(19) United States
(12) Patent Application Publication
(10) Pub. No.: US 2024/0105536 A1
(43) Pub. Date: Mar. 28, 2024

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Seokbong PARK, Suwon-si (KR); Sechul PARK, Suwon-si (KR); Unbyoung KANG, Suwon-si (KR); Junhyun AN, Suwon-si (KR); Hyojin YUN, Suwon-si (KR); Seunghun CHAE, Suwon-si (KR)

(73) Assignee: SAMSUNG ELECTRONICS CO., LTD., Suwon-si (KR)

(21) Appl. No.: 18/369,474

(22) Filed: Sep. 18, 2023

(30) Foreign Application Priority Data
Sep. 23, 2022 (KR) 10-2022-0121145

(51) Int. Cl. H01L 23/31; H01L 23/00; H01L 23/498; H01L 25/10

(52) U.S. Cl. CPC H01L 23/3107; H01L 23/49822; H01L 23/49838; H01L 23/49866; H01L 24/16; H01L 25/105; H01L 2224/16227; H01L 2224/16238; H01L 2225/1023; H01L 2225/1041; H01L 2924/15174

(57) ABSTRACT

A semiconductor package includes a first redistribution structure, a first semiconductor chip on the first redistribution structure, a first molding layer on the first redistribution structure, the first molding layer including at least one lower recess in a top surface thereof and being disposed on the first semiconductor chip, connection structures on the first redistribution structure, the connection structures extending in a vertical direction and passing through the first molding layer, a first insulating layer on the first molding layer, and a second redistribution structure including a lower redistribution insulating layer on the first insulating layer, wherein the first insulating layer at least partially fills the at least one lower recess of the first molding layer.

### CROSS-REFERENCE TO RELATED APPLICATION

This application claims priority to Korean Patent Application No. 10-2022-0121145, filed on Sep. 23, 2022, in the Korean Intellectual Property Office, the disclosure of which is incorporated by reference herein in its entirety.

### BACKGROUND

The disclosure relates to a semiconductor package and a method of manufacturing the same.

With the development of the electronics industry and user needs, electronic components mounted on electronic products have become increasingly compact and light. With the compactness and lightness of electronic devices, semiconductor packages used in electronic devices have also become compact and light and may be required to have high performance, high capacity, and high reliability. Therefore, the importance of the structure of a semiconductor package, which secures the reliability of the semiconductor package, is increasing.

### SUMMARY

One or more example embodiment provides a semiconductor package with an increased structural reliability.

One or more example embodiment provides a method of manufacturing a semiconductor package with an increased structural reliability.

According to an aspect of an example embodiment, a semiconductor package includes: a first redistribution structure; a first semiconductor chip on the first redistribution structure; a first molding layer on the first redistribution structure, the first molding layer comprising at least one lower recess in a top surface thereof and being disposed on the first semiconductor chip; connection structures on the first redistribution structure, the connection structures extending in a vertical direction and passing through the first molding layer; a first insulating layer on the first molding layer; and a second redistribution structure comprising a lower redistribution insulating layer on the first insulating layer, wherein the first insulating layer at least partially fills the at least one lower recess of the first molding layer.

According to an aspect of an example embodiment, a semiconductor package includes: a lower semiconductor package; an upper semiconductor chip mounted on the lower semiconductor package; and an upper molding layer on the lower semiconductor package, the upper molding layer disposed on the upper semiconductor chip, wherein the lower semiconductor package comprises a first redistribution structure; a first semiconductor chip on the first redistribution structure; a first molding layer on the first redistribution structure, the first molding layer comprising at least one lower recess in a top surface thereof and being disposed on the first semiconductor chip; connection structures on the first redistribution structure, the connection structures extending in a vertical direction and passing through the first molding layer; a first insulating layer on the first molding layer; and a second redistribution structure comprising a lower redistribution insulating layer on the first insulating layer, wherein the first insulating layer at least partially fills the at least one lower recess of the first molding layer.

According to an aspect of an example embodiment, a semiconductor package includes: a first redistribution structure; a first semiconductor chip on the first redistribution structure; a first molding layer on the first redistribution structure, the first molding layer disposed on the first semiconductor chip and comprising a first lower recess and a second lower recess in a top surface thereof; connection structures on the first redistribution structure, the connection structures extending in a vertical direction and passing through the first molding layer; a first insulating layer on the first molding layer; and a second redistribution structure comprising a lower redistribution insulating layer and a lower redistribution via passing through the first insulating layer and the lower redistribution insulating layer, wherein the first insulating layer comprises a non-photo-imageable dielectric, the lower redistribution insulating layer comprises a photo-imageable dielectric, and the first insulating layer at least partially fills the first lower recess and the second lower recess.

According to an aspect of an example embodiment, a method of manufacturing a semiconductor package includes: mounting a first semiconductor chip on a first redistribution structure having a connection structure formed thereon; forming a first molding layer on the first redistribution structure, the first molding layer being disposed on the first semiconductor chip; performing planarization of the first molding layer; forming a first insulating layer on the first molding layer and the connection structure; forming a lower redistribution insulating layer on the first insulating layer; forming a lower redistribution insulating layer trench exposing the first insulating layer; forming a first insulating layer trench exposing the connection structure; forming a lower redistribution via filling the lower redistribution insulating layer trench and the first insulating layer trench; and forming a second redistribution structure by forming an upper redistribution insulating layer and a second redistribution pattern on the lower redistribution insulating layer, wherein the first insulating layer at least partially fills at least one recess in a top surface of the first molding layer.

### BRIEF DESCRIPTION OF DRAWINGS

The above and other aspects and features will be more apparent from the following description of example embodiments, taken in conjunction with the accompanying drawings, in which:

FIG. 1 is a cross-sectional view of a semiconductor package according to an embodiment;

FIG. 2 is an enlarged cross-sectional view of regions EX1 and EX2 in FIG. 1;

FIGS. 3A to 3C are enlarged cross-sectional views of portions corresponding to the region EXT in FIG. 1;

FIGS. 4A and 4B are enlarged cross-sectional views of portions corresponding to the region EXT in FIG. 1;

FIG. 5 is a cross-sectional view of a semiconductor package according to an embodiment;

FIG. 6 is a flowchart of a method of manufacturing a semiconductor package, according to an embodiment; and

FIGS. 7A to 7I are cross-sectional views of stages in a method of manufacturing a semiconductor package, according to an embodiment.

### DETAILED DESCRIPTION

Example embodiments will be described more fully with reference to the accompanying drawings, in which example embodiments are shown. Embodiments described herein are provided as examples, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. In the drawing, like reference characters denote like elements, and redundant descriptions thereof will be omitted.

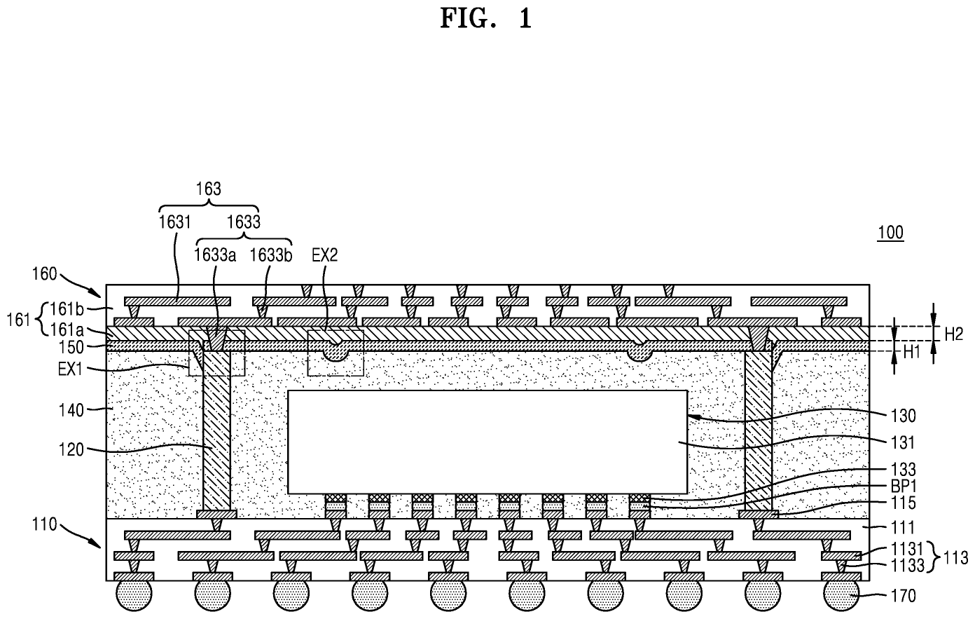

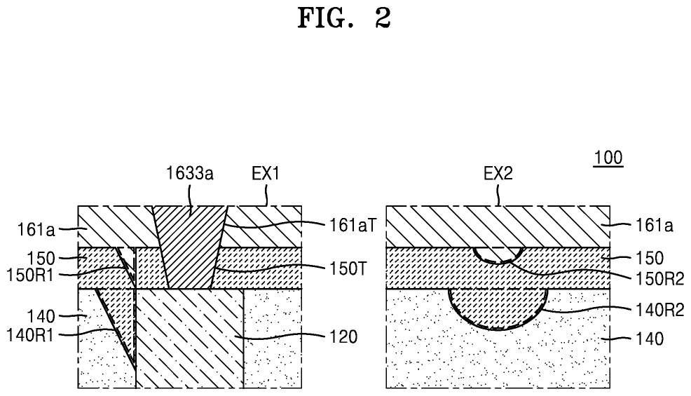

FIG. 1 is a cross-sectional view of a semiconductor package according to an embodiment. FIG. 2 is an enlarged cross-sectional view of regions EX1 and EX2 in FIG. 1.

Referring to FIGS. 1 and 2, a semiconductor package 100 may include a first redistribution structure 110, connection structures 120, a first semiconductor chip 130, a first molding layer 140, a gap-fill insulating layer 150, and a second redistribution structure 160.

The first redistribution structure 110 may correspond to a substrate, on which the first semiconductor chip 130 is mounted. The first redistribution structure 110 may include a first redistribution insulating layer 111 and a first redistribution pattern 113. Hereinafter, unless described otherwise, a direction parallel with the top surface of the first redistribution structure 110 may be defined as a horizontal direction (e.g., the X direction and the Y direction), and a direction perpendicular to the top surface of the first redistribution structure 110 may be defined as a vertical direction (e.g., the Z direction).

The first redistribution insulating layer 111 may be disposed on or cover the first redistribution pattern 113. The first redistribution insulating layer 111 may include a plurality of insulating layers stacked in the vertical direction or may include only a single insulating layer. The first redistribution insulating layer 111 may include, for example, one or more of a photo-imageable dielectric (PID) or a photosensitive polyimide (PSPI).

The first redistribution pattern 113 may include a plurality of first redistribution lines 1131, which extend in the horizontal direction, and a plurality of first redistribution vias 1133, which extend at least partially passing through the first redistribution insulating layer 111. The plurality of first redistribution vias 1133 may extend in a vertical direction. The first redistribution lines 1131 may extend in the horizontal direction along at least one of the top and bottom surfaces of each of the insulating layers of the first redistribution insulating layer 111. In an embodiment, at least some of the first redistribution lines 1131 may be at a different vertical level than the others of the first redistribution lines 1131. The first redistribution vias 1133 may electrically connect the first redistribution lines 1131 that are disposed at different vertical levels to each other. In an embodiment, a horizontal width of each of the first redistribution vias 1133 may increase toward the first semiconductor chip 130. That is, in an embodiment, a portion of each of the first redistribution vias 113 that is relatively near the first semiconductor chip 130 may have a horizontal width that is larger than the horizontal width of a portion of the first redistribution via 113 relatively far from the first semiconductor chip 130, though embodiments are not limited thereto. In an embodiment, the first redistribution pattern 113 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof. The first redistribution pattern 113 may include a plurality of first redistribution pads 115 at the top thereof. The bottom surface of each of the first redistribution pads 115 may have the first redistribution insulating layer 111 disposed thereon or be covered with the first redistribution insulating layer 111.

The connection structures 120 may be on the first redistribution structure 110. The connection structures 120 may be respectively connected to the first redistribution pads 115 of the first redistribution structure 110. The connection structures 120 may extend in the vertical direction and pass through the first molding layer 140. In an embodiment, each of the connection structures 120 may correspond to a conductive pillar including copper. The first redistribution structure 110 may be electrically connected to the second redistribution structure 160 by the connection structures 120.

The first semiconductor chip 130 may be on the first redistribution structure 110 and spaced apart from the connection structures 120 in the horizontal direction. In detail, the first semiconductor chip 130 may be on the central portion of the first redistribution structure 110, and the connection structures 120 may be spaced apart from and surround the first semiconductor chip 130. In an embodiment, the first semiconductor chip 130 may be a memory chip or a logic chip, for example. For example, the memory chip may include a volatile memory chip, such as a dynamic random access memory (DRAM) chip or a static RAM (SRAM) chip, or a non-volatile memory chip, such as a phase-change RAM (PRAM) chip, a magnetoresistive RAM (MRAM) chip, a ferroelectric RAM (FeRAM) chip, or a resistive RAM (RRAM) chip. For example, the logic chip may include a microprocessor, an analog element, or a digital signal processor. The first semiconductor chip 130 may include a first semiconductor substrate 131 and a first chip pad 133.

The first semiconductor substrate 131 may include a Group IV semiconductor, such as silicon (Si) or germanium (Ge), a Group IV-IV compound semiconductor, such as silicon germanium (SiGe) or silicon carbide (SiC), or a Group III-V compound semiconductor, such as gallium arsenide (GaAs), indium arsenide (InAs), or indium phosphide (InP). The first semiconductor substrate 131 may include a conductive region, e.g., an impurity-doped well. The first semiconductor substrate 131 may have various device isolation structures such as a shallow trench isolation (STI) structure.

The first semiconductor substrate 131 may have a first active surface and a first inactive surface opposite to the first active surface. The first active surface of the first semiconductor substrate 131 may correspond to the bottom surface of the first semiconductor substrate 131, which faces the second redistribution structure 160, and the first inactive surface of the first semiconductor substrate 131 may correspond to the top surface of the first semiconductor substrate 131, which faces the first redistribution structure 110. Various kinds of individual devices may be on the first active surface of the first semiconductor substrate 131. The individual devices may include various microelectronic devices, e.g., a metal-oxide-semiconductor field effect transistor (MOSFET) such as a complementary metal-oxide-semiconductor (CMOS) transistor, a system large scale integration (LSI), an image sensor such as a CMOS image sensor (CIS), a micro-electro-mechanical system (MEMS), an active element, and a passive element. The individual devices may be electrically connected to the conductive region of the first semiconductor substrate 131. Each of the individual devices may be electrically isolated from other neighboring individual devices by an insulating layer (not shown).

A first connection terminal BP1 may be between the first semiconductor chip 130 and the first redistribution structure 110. The first connection terminal BPT may be in contact with the first chip pad 133 of the first semiconductor chip 130 and the first redistribution pads 115 of the first redistribution structure 110 and may physically and electrically connect the first semiconductor chip 130 to the first redistribution structure 110. For example, the first connection terminal BPT may include at least one of or at least one selected from the group consisting of solder, Sn, silver (Ag), Cu, and Al.

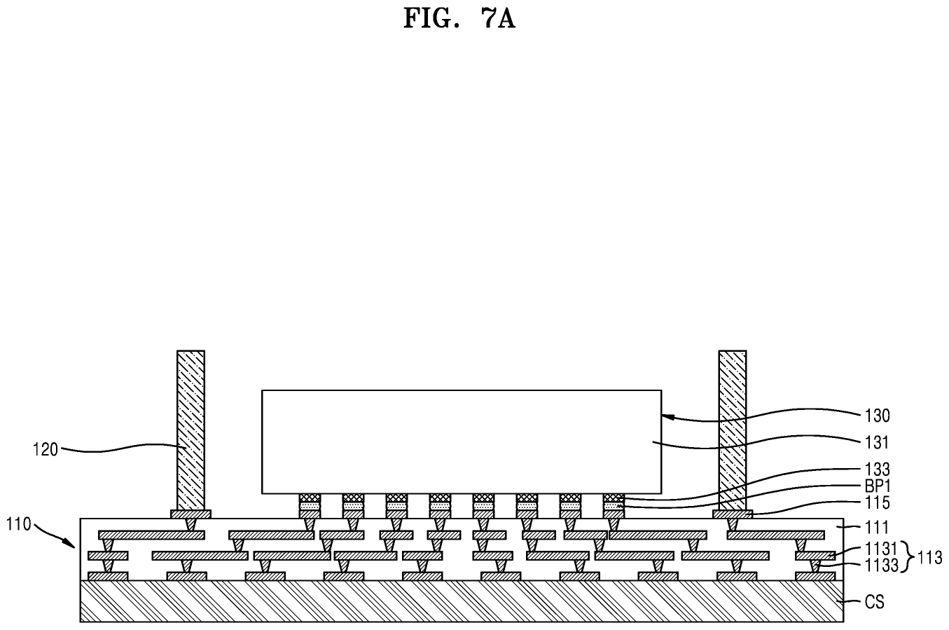

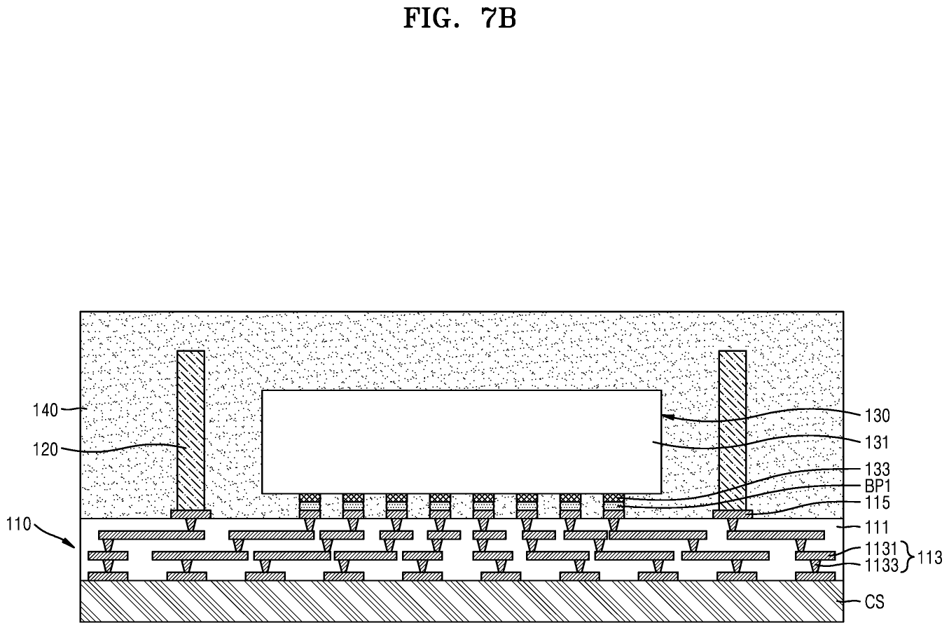

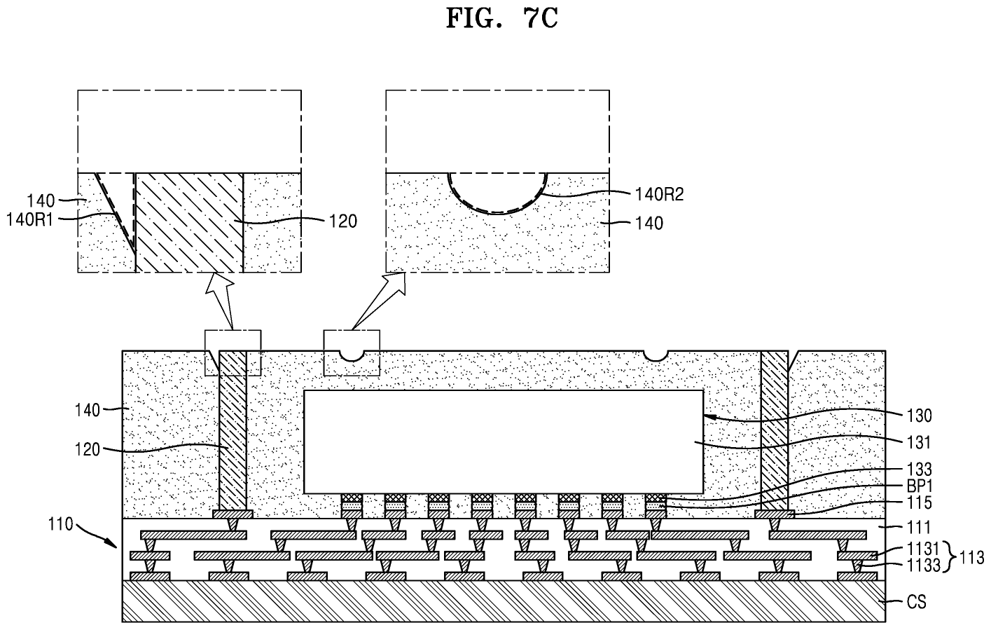

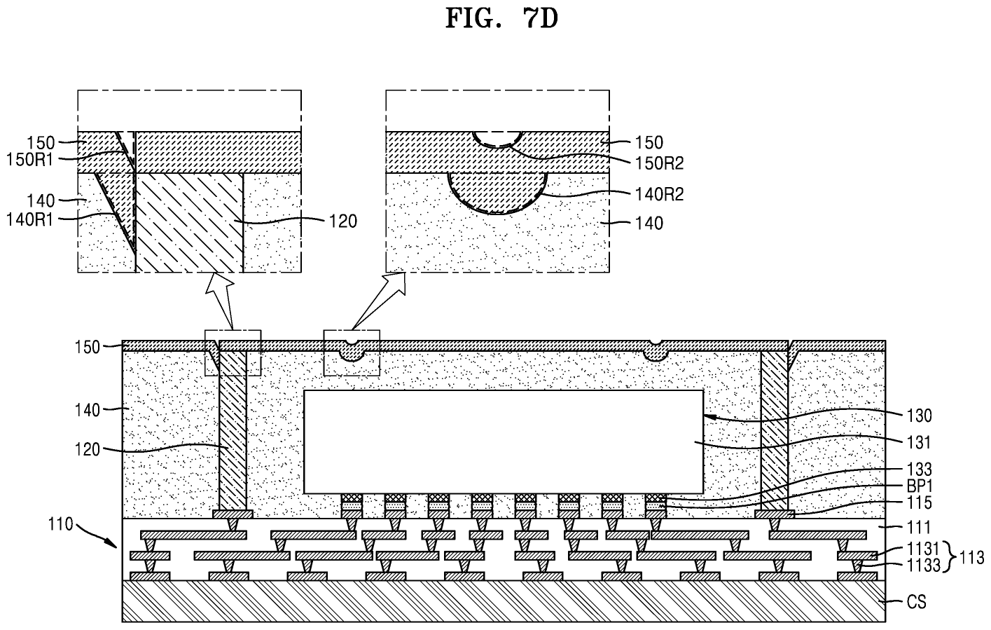

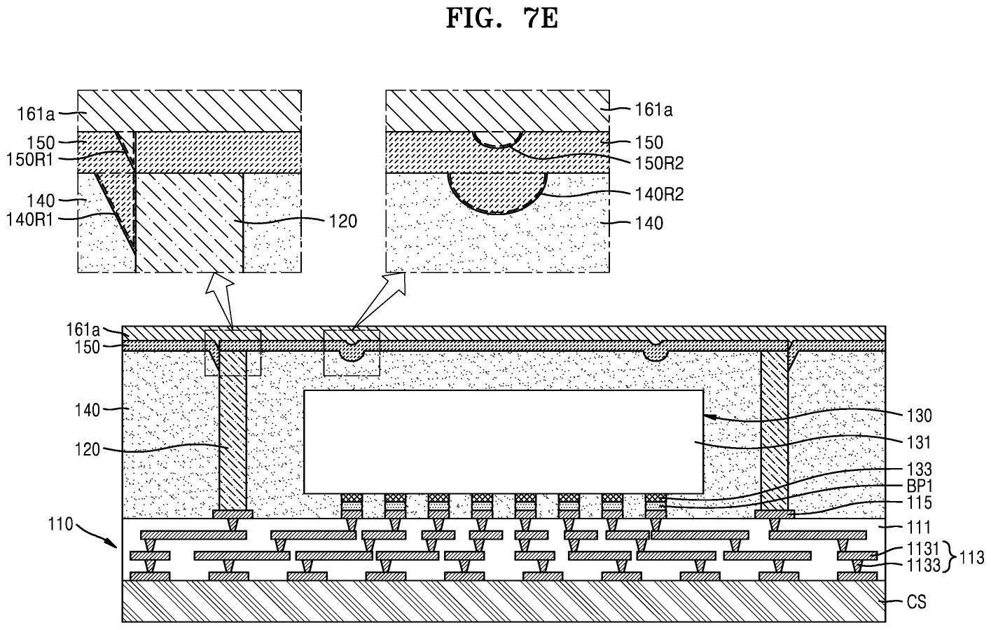

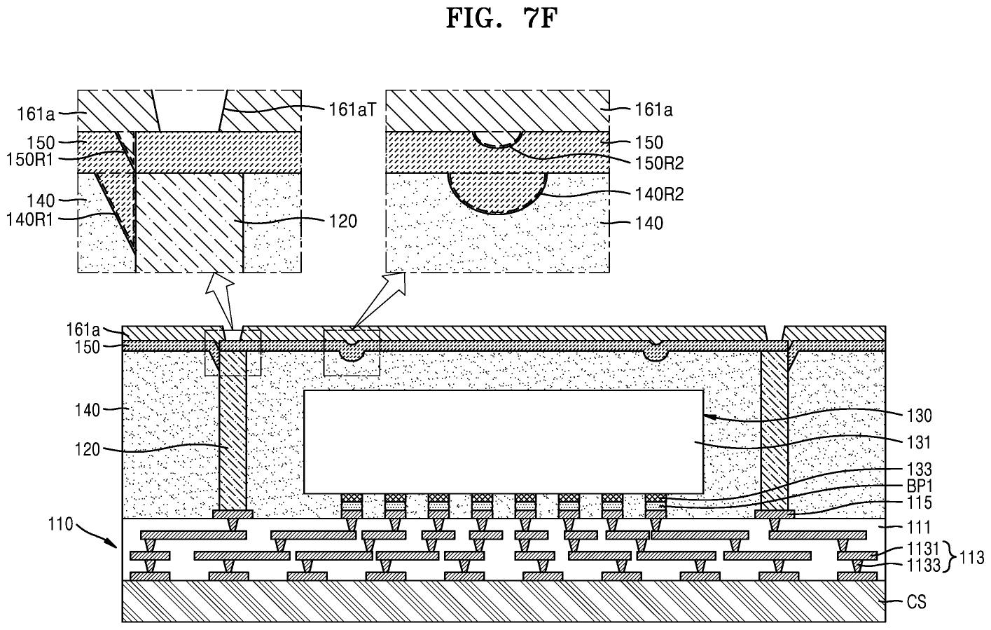

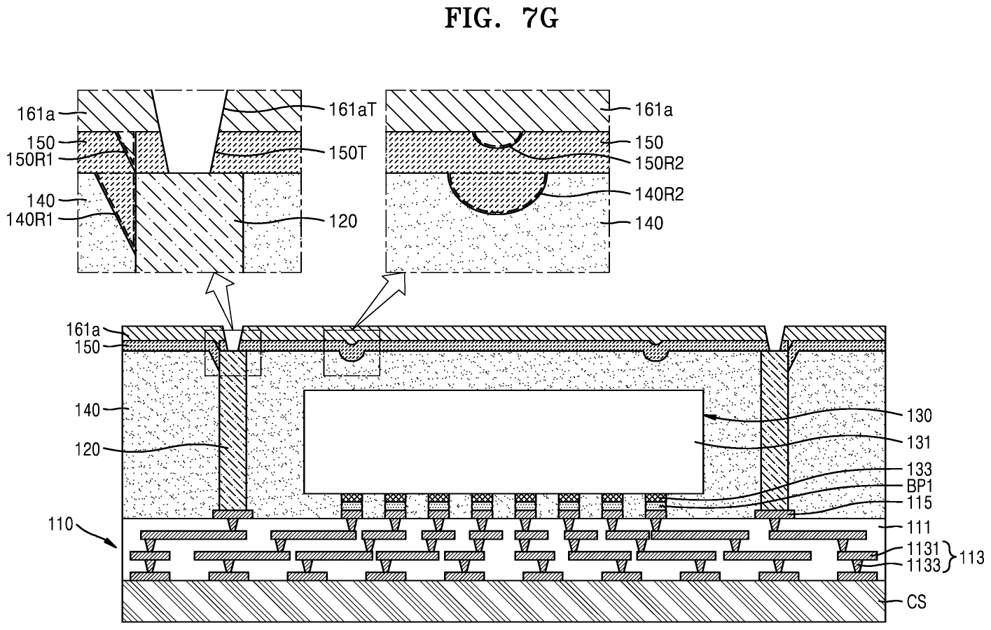

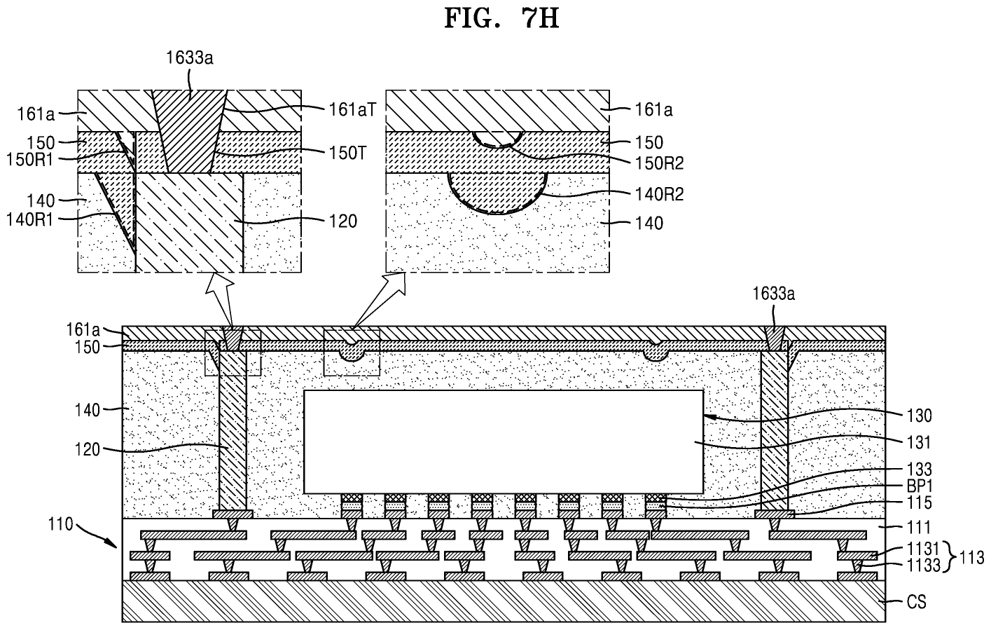

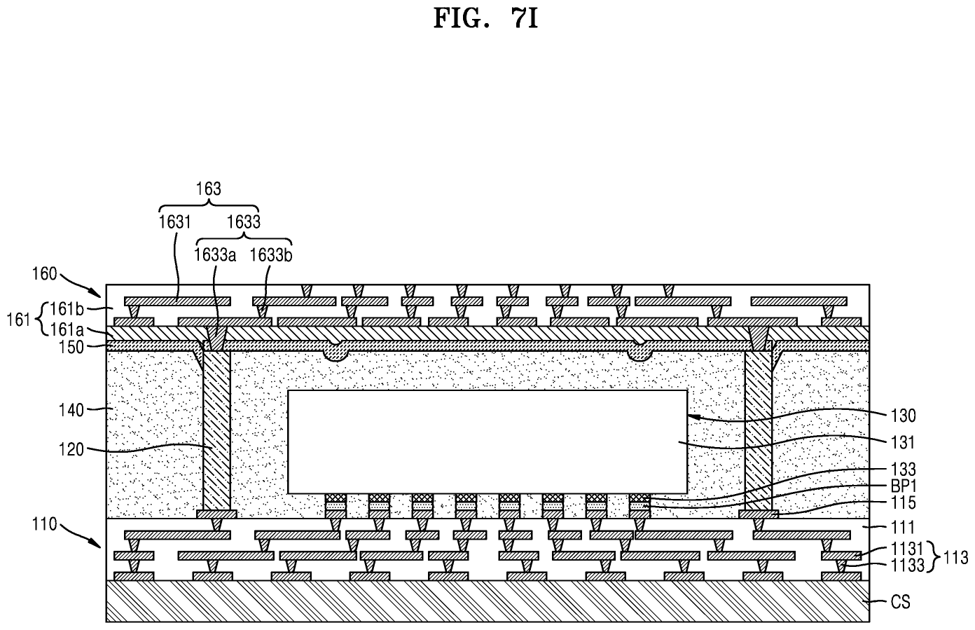

The first molding layer 140 may be on the first redistribution structure 110 and may be disposed on or cover at least a portion of the first semiconductor chip 130. In detail, the first molding layer 140 may extend along and be disposed on or cover the top and bottom surfaces and both side walls of the first semiconductor chip 130. In an embodiment, the first molding layer 140 may include a first lower recess 140R1 and a second lower recess 140R2. The first lower recess 140R1 may be at an interface between the first molding layer 140 and each of the connection structures 120. For example, the first lower recess 140R1 may have a triangle shape in a cross-sectional view, but embodiments are not limited thereto. The second lower recess 140R2 may be at the top surface of the first molding layer 140. For example, the second lower recess 140R2 may be at a portion of the top surface of the first molding layer 140, which overlaps with the first semiconductor chip 130 in the vertical direction, or the other portion of the top surface of the first molding layer 140, which does not overlap with the first semiconductor chip 130 in the vertical direction. For example, the second lower recess 140R2 may have a semicircular shape in a cross-sectional view but is not limited thereto. The first lower recess 140R1 and the second lower recess 140R2 may be formed during planarization of the first molding layer 140, which is described with reference to FIG. 7C below. In detail, the first lower recess 140R1 may be formed as the first molding layer 140 is delaminated from each of the connection structures 120 by the planarization, and the second lower recess 140R2 may be formed as a filler or the like comes out of the first molding layer 140 because of the planarization. In an embodiment, the first molding layer 140 may include an insulating polymer or epoxy resin. For example, the first molding layer 140 may include an epoxy molding compound (EMC).

The gap-fill insulating layer 150 may be on the first molding layer 140. The gap-fill insulating layer 150 may fill the first lower recess 140R1 and the second lower recess 140R2. In an embodiment, the gap-fill insulating layer 150 may include a non-PID. In an embodiment, the material of the gap-fill insulating layer 150 may be different from the material of the first molding layer 140. In an embodiment, the viscosity of the gap-fill insulating layer 150 may be in a range of from about 1000 cp to about 2000 cp. When the viscosity of the gap-fill insulating layer 150 is less than about 1000 cp or greater than about 2000 cp, the gap-fill insulating layer 150 may not completely fill the first and second lower recesses 140R1 and 140R2.

The gap-fill insulating layer 150 may include a first upper recess 150R1 and a second upper recess 150R2. The first upper recess 150R1 and the second upper recess 150R2 may be formed as the gap-fill insulating layer 150 fills the first lower recess 140R1 and the second lower recess 140R2. The first upper recess 150R1 may overlap with the first lower recess 140R1 in the vertical direction. The second upper recess 150R2 may overlap with the second lower recess 140R2 in the vertical direction. In an embodiment, the first upper recess 150R1 may have a planar shape that is substantially the same as or similar to the planar shape of the first lower recess 140R1, and the second upper recess 150R2 may have a planar shape that is substantially the same as or similar to the planar shape of the second lower recess 140R2. For example, the first upper recess 150R1 may have a planar shape and/or a cross-sectional shape that is substantially the same as or similar to the planar shape and/or the cross-sectional shape of the first lower recess 140R1. For example, the first upper recess 150R1 and the first lower recess 140R1 may have a triangle shape in a cross-sectional view, and the second upper recess 150R2 and the second lower recess 140R2 may have a semicircular shape in a cross-sectional view. In an embodiment, the lengths of the first upper recess 150R1 respectively in the horizontal and vertical directions may be respectively less than the lengths of the first lower recess 140R1 respectively in the horizontal and vertical directions, and the lengths of the second upper recess 150R2 respectively in the horizontal and vertical directions may be respectively less than the lengths of the second lower recess 140R2 respectively in the horizontal and vertical directions.

The second redistribution structure 160 may be on the gap-fill insulating layer 150. The second redistribution structure 160 may include a second redistribution insulating layer 161 and a second redistribution pattern 163.

The second redistribution insulating layer 161 may include a lower redistribution insulating layer 161a and an upper redistribution insulating layer 161b. The lower redistribution insulating layer 161a may be on the gap-fill insulating layer 150. The lower redistribution insulating layer 161a may fill the first upper recess 150R1 and the second upper recess 150R2. In an embodiment, a vertical thickness H2 of the lower redistribution insulating layer 161a may be greater than a vertical thickness H1 of the gap-fill insulating layer 150. In an embodiment, the lower redistribution insulating layer 161a may include a PID or PSPI. In an embodiment, the glass transition temperature (Tg) of the lower redistribution insulating layer 161a may be lower than the Tg of the gap-fill insulating layer 150. In an embodiment, the 5% weight loss temperature (Td5) of the lower redistribution insulating layer 161a may be lower than the Td5 of the gap-fill insulating layer 150. Here, Td5 refers to a temperature at which the mass of a material is reduced by 5%, and may be a property of the material, in particular a property of the material related to the heat resistance of the material.

The upper redistribution insulating layer 161b may be on the lower redistribution insulating layer 161a. The upper redistribution insulating layer 161b may be disposed on or cover the second redistribution pattern 163. The upper redistribution insulating layer 161b may include a plurality of insulating layers stacked in the vertical direction or a single insulating layer. For example, the upper redistribution insulating layer 161b may include a PID or PSPI.

The second redistribution pattern 163 may include a plurality of second redistribution lines 1631, which extend in the horizontal direction, and a plurality of second redistribution vias 1633, which may extend in the vertical direction. The second redistribution lines 1631 may extend in the horizontal direction along at least one of the top and bottom surfaces of each of the insulating layers of the upper redistribution insulating layer 161b. At this time, at least some of the second redistribution lines 1631 may be at a different vertical level than the others of the second redistribution lines 1631.

The second redistribution vias 1633 may include a lower redistribution via 1633a and an upper redistribution via 1633b.

The lower redistribution via 1633a may correspond to a lowest second redistribution via 1633. The lower redistribution via 1633a may be formed in a gap-fill insulating layer trench 150T and a lower redistribution insulating layer trench 161aT. The lower redistribution via 1633a may extend passing through the gap-fill insulating layer 150 and the lower redistribution insulating layer 161a. In an embodiment, a horizontal width of the lower redistribution via 1633a may decrease toward the first semiconductor chip 130. The lower redistribution via 1633a may electrically connect a second redistribution line 1631 thereon to a connection structure 120.

The upper redistribution via 1633b may correspond to one of the second redistribution vias 1633 other than lowest redistribution vias 1633a at the bottom among the second redistribution vias 1633. The upper redistribution via 1633b may extend in the vertical direction and at least partially pass through the upper redistribution insulating layer 161b. The upper redistribution via 1633b may electrically connect a plurality of second redistribution lines 1631 respectively at different vertical levels. In an embodiment, a horizontal width of the upper redistribution via 1633b may decrease toward the first semiconductor chip 130, but embodiments are not limited thereto. In an embodiment, the second redistribution pattern 163 may include a metal, such as Cu, Al, W, Ti, Ta, In, Mo, Mn, Co, Sn, Ni, Mg, Re, Be, Ga, or Ru, or an alloy thereof.

The semiconductor package 100 may further include a plurality of external connection terminals 170. The external connection terminals 170 may be on the bottom surface of the first redistribution structure 110. Some of the external connection terminals 170 may overlap with the first semiconductor chip 130 in the vertical direction, and the others of the external connection terminals 170 may not overlap with the first semiconductor chip 130 in the vertical direction. For example, the external connection terminals 170 may include solder. The external connection terminals 170 may physically and electrically connect the semiconductor package 100 to an external device.

According to an embodiment, the semiconductor package 100 includes the gap-fill insulating layer 150 between the second redistribution structure 160 and the first molding layer 140, and the gap-fill insulating layer 150 fills the first lower recess 140R1 and the second lower recess 140R2. Accordingly, the first lower recess 140R1 and the second lower recess 140R2, which are formed during the planarization of the first molding layer 140 because a filler comes out of the first molding layer 140 or the first molding layer 140 is delaminated from each of the connection structures 120, may be filled or at least partially filled with the gap-fill insulating layer 150. As a result, the structural reliability of the semiconductor package 100 may be increased.

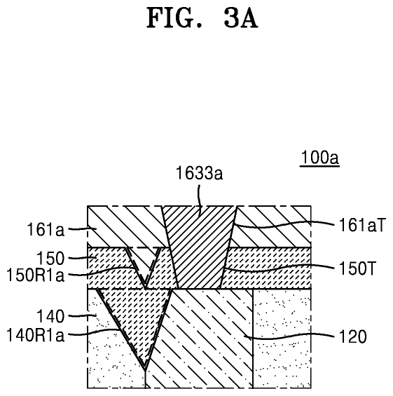

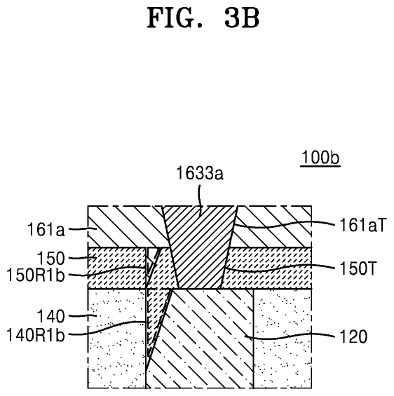

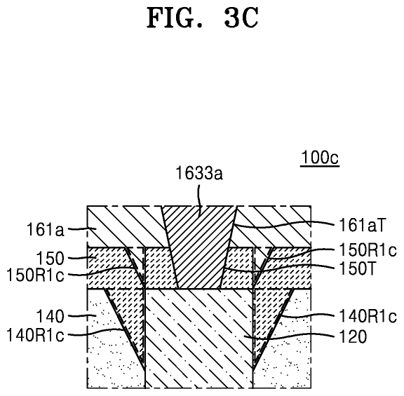

FIGS. 3A to 3C are enlarged cross-sectional views of portions corresponding to the region EX1 in FIG. 1. The elements of each of semiconductor packages 100a, 100b, and 100c respectively illustrated in FIGS. 3A to 3C are substantially the same as or similar to those of the semiconductor package 100 described with reference to FIGS. 1 and 2, and thus, differences therebetween are mainly described below.

Referring to FIG. 3A, the semiconductor package 100a may have a first lower recess 140R1a at an interface between the first molding layer 140 and a connection structure 120. The first lower recess 140R1a may be formed during the planarization of the first molding layer 140 because a portion of the first molding layer 140 and a portion of the connection structure 120 are delaminated from each other at the interface therebetween. In an embodiment, the first lower recess 140R1a may have a triangle shape. The first lower recess 140R1a may be filled or at least partially filled with the gap-fill insulating layer 150. The gap-fill insulating layer 150 may have a first upper recess 150R1a at the top surface thereof. The first upper recess 150R1a may overlap with the first lower recess 140R1a in the vertical direction. The first upper recess 150R1a may have a triangle shape. The first upper recess 150R1a may be filled or at least partially filled with the lower redistribution insulating layer 161a.

Referring to FIG. 3B, the semiconductor package 100b may have a first lower recess 140R1b at an interface between the first molding layer 140 and the connection structure 120. The first lower recess 140R1b may be formed during the planarization of the first molding layer 140 because a portion of the connection structure 120 is delaminated from the interface between the first molding layer 140 and the connection structure 120. In an embodiment, the first lower recess 140R1b may have a triangle shape. The first lower recess 140R1b may be filled or at least partially filled with the gap-fill insulating layer 150. The gap-fill insulating layer 150 may have a first upper recess 150R1b at the top surface thereof. The first upper recess 150R1b may overlap with the first lower recess 140R1b in the vertical direction. The first upper recess 150R1b may have a triangle shape. The first upper recess 150R1b may be filled or at least partially filled with the lower redistribution insulating layer 161a.

Referring to FIG. 3C, the semiconductor package 100c may have a first lower recess 140R1c in an interface between the first molding layer 140 and the connection structure 120. The first lower recess 140R1c may be formed during the planarization of the first molding layer 140 because a portion of the first molding layer 140 is delaminated from the interface between the first molding layer 140 and the connection structure 120. At this time, the first lower recess 140R1c may be around or surround the side wall of the connection structure 120. In an embodiment, the first lower recess 140R1c may have a triangle shape. The first lower recess 140R1c may be filled or at least partially filled with the gap-fill insulating layer 150. The gap-fill insulating layer 150 may have a first upper recess 150R1c in the top surface thereof. The first upper recess 150R1c may overlap with the first lower recess 140R1c in the vertical direction. The first upper recess 150R1c may have a triangle shape. The first upper recess 150R1c may be filled or at least partially filled with the lower redistribution insulating layer 161a. Although the first lower recess 140R1c partially passes through only the first molding layer 140 in FIG. 3C, embodiments are not limited thereto. For example, the first lower recess 140R1c may partially pass through only the connection structure 120 or partially pass through the connection structure 120 and the first molding layer 140, as shown in FIG. 3A or 3B.

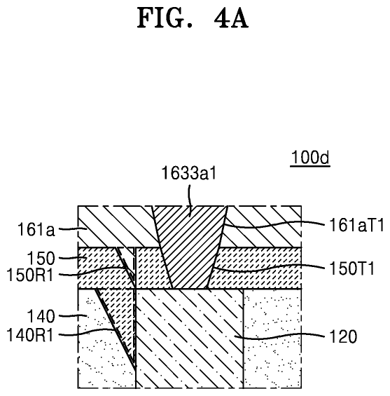

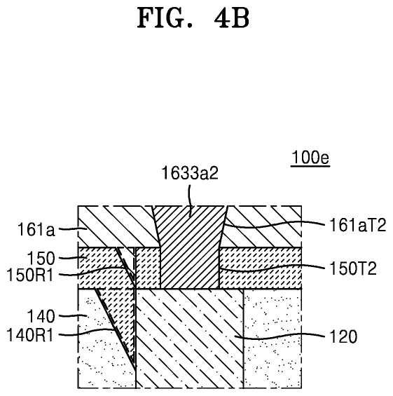

FIGS. 4A and 4B are enlarged cross-sectional views of portions corresponding to the region EX1 in FIG. 1. The elements of each of semiconductor packages 100d and 100e respectively illustrated in FIGS. 4A and 4B are substantially the same as or similar to those of the semiconductor package 100 described with reference to FIGS. 1 and 2, and thus, differences therebetween are mainly described below. Although the shape of the first lower recess 140R1 in FIGS. 4A and 4B is substantially the same as that of the first lower recess 140R1 in FIG. 2, embodiments are not limited thereto. For example, the shape of the first lower recess 140R1 in FIGS. 4A and 4B may be substantially the same as that of the first lower recess 140R1a, 140R1b, or 140R1c in FIG. 3A, 3B, or 3C.

Referring to FIG. 4A, the semiconductor package 100d may include a lower redistribution via 1633a1, which extends in the vertical direction and passes through the gap-fill insulating layer 150 and the lower redistribution insulating layer 161a. The lower redistribution via 1633a1 may fill or at least partially fill a gap-fill insulating layer trench 150T1 and a lower redistribution insulating layer trench 161aT1. In an embodiment, a horizontal width of each of the gap-fill insulating layer trench 150T1 and the lower redistribution insulating layer trench 161aT1 may decrease toward the connection structure 120. At this time, the slope of the gap-fill insulating layer trench 150T1 may be less than the slope of the lower redistribution insulating layer trench 161aT1. Accordingly, while a horizontal width of the lower redistribution via 1633a1, which fills the gap-fill insulating layer trench 150T1 and the lower redistribution insulating layer trench 161aT1, decreases relatively slowly from the top surface of the lower redistribution insulating layer 161a to the bottom surface of the lower redistribution insulating layer 161a, the horizontal width of the lower redistribution via 1633a1 may decrease relatively quickly from the bottom surface of the lower redistribution insulating layer 161a (i.e., the top surface of the gap-fill insulating layer 150) to the bottom surface of the gap-fill insulating layer 150.

In an embodiment, unlike FIG. 4A, the slope of the gap-fill insulating layer trench 150T1 may be greater than the slope of the lower redistribution insulating layer trench 161aT1. Accordingly, the horizontal width of the lower redistribution via 1633a1, which fills the gap-fill insulating layer trench 150T1 and the lower redistribution insulating layer trench 161aT1, may decrease relatively quickly from the top surface of the lower redistribution insulating layer 161a to the bottom surface of the lower redistribution insulating layer 161a and decrease relatively slowly from the bottom surface of the lower redistribution insulating layer 161a (i.e., the top surface of the gap-fill insulating layer 150) to the bottom surface of the gap-fill insulating layer 150.

Referring to FIG. 4B, the semiconductor package 100e may include a lower redistribution via 1633a2, which extends in the vertical direction and passes through the gap-fill insulating layer 150 and the lower redistribution insulating layer 161a. The lower redistribution via 1633a2 may fill or at least partially fill a gap-fill insulating layer trench 150T2 and a lower redistribution insulating layer trench 161aT2. In an embodiment, a horizontal width of the gap-fill insulating layer trench 150T2 is constant, and a horizontal width of the lower redistribution insulating layer trench 161aT2 may decrease toward the connection structure 120. Accordingly, a horizontal width of the lower redistribution via 1633a2, which fills the gap-fill insulating layer trench 150T2 and the lower redistribution insulating layer trench 161aT2, may decrease from the top surface of the lower redistribution insulating layer 161a to the bottom surface of the lower redistribution insulating layer 161a and may be constant from the bottom surface of the lower redistribution insulating layer 161a (i.e., the top surface of the gap-fill insulating layer 150) to the bottom surface of the gap-fill insulating layer 150.

In another embodiment, unlike what is illustrated in the embodiment of FIG. 4B, the horizontal width of the gap-fill insulating layer trench 150T2 may decrease toward the connection structure 120, and the horizontal width of the lower redistribution insulating layer trench 161aT2 may be constant. Accordingly, the horizontal width of the lower redistribution via 1633a2, which fills the gap-fill insulating layer trench 150T2 and the lower redistribution insulating layer trench 161aT2, may be constant from the top surface of the lower redistribution insulating layer 161a to the bottom surface of the lower redistribution insulating layer 161a and may decrease from the bottom surface of the lower redistribution insulating layer 161a (i.e., the top surface of the gap-fill insulating layer 150) to the bottom surface of the gap-fill insulating layer 150.

In an embodiment, unlike what is illustrated in the embodiment of FIG. 4B, the horizontal width of each of the gap-fill insulating layer trench 150T2 and the lower redistribution insulating layer trench 161aT2 may be constant. Accordingly, the horizontal width of the lower redistribution via 1633a2, which fills the gap-fill insulating layer trench 150T2 and the lower redistribution insulating layer trench 161aT2, may be constant from the top surface of the lower redistribution insulating layer 161a to the bottom surface of the gap-fill insulating layer 150.

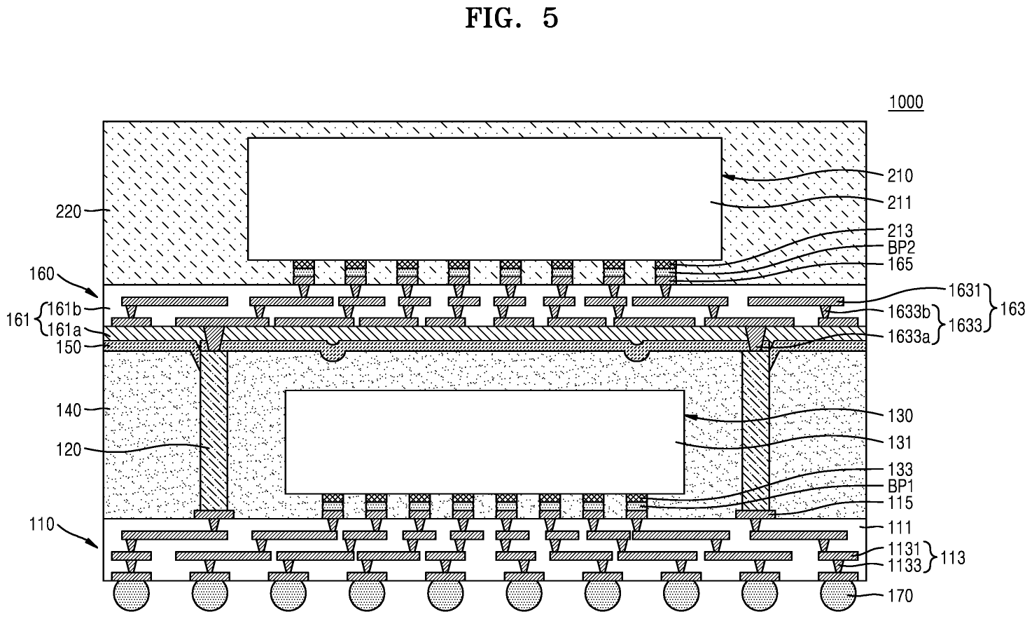

FIG. 5 is a cross-sectional view of a semiconductor package 1000 according to an embodiment.

Referring to FIG. 5, the semiconductor package 1000 may include the semiconductor package 100 of FIG. 1, a second semiconductor chip 210, and a second molding layer 220.

The semiconductor package 100 may include the first redistribution structure 110, the connection structures 120, the first semiconductor chip 130, the first molding layer 140, the gap-fill insulating layer 150, the second redistribution structure 160, and the external connection terminals 170. Each element of the semiconductor package 100 has been described with reference to FIGS. 1 and 2, and thus, detailed descriptions thereof are omitted below.

The second semiconductor chip 210 may be on the semiconductor package 100. The second semiconductor chip 210 may be a memory chip or a logic chip. For example, the memory chip may include a volatile memory chip, such as a DRAM chip or an SRAM chip, or a non-volatile memory chip, such as a PRAM chip, an MRAM chip, an FeRAM chip, or an RRAM chip. For example, the logic chip may include a microprocessor, an analog element, or a digital signal processor.

The first semiconductor chip 130 and the second semiconductor chip 210 may be homogeneous or heterogeneous. In embodiments, each of the first semiconductor chip 130 and the second semiconductor chip 210 may include a logic chip. In embodiments, one of the first semiconductor chip 130 and the second semiconductor chip 210 may include a logic chip, and the other one may correspond to a memory chip.

The second semiconductor chip 210 may include a second semiconductor substrate 211 and a second chip pad 213. The second semiconductor substrate 211 may include a material that is the same as or similar to the material of the first semiconductor substrate 131. The second semiconductor substrate 211 may include a conductive region, e.g., an impurity-doped well. The second semiconductor substrate 211 may have various device isolation structures such as an STI structure.

The second semiconductor substrate 211 may have a second active surface and a second inactive surface opposite to the second active surface. Various kinds of individual devices may be on the second active surface of the second semiconductor substrate 211.

A second connection terminal BP2 may be between the second semiconductor chip 210 and the second redistribution structure 160. The second connection terminal BP2 may be in contact with the second chip pad 213 of the second semiconductor chip 210 and a second redistribution pad 165 of the second redistribution structure 160 and may physically and electrically connect the second semiconductor chip 210 to the second redistribution structure 160. The second connection terminal BP2 may include a material that is the same as or similar to a material of the first connection terminal BP1.

The second molding layer 220 may be on the second redistribution structure 160 and may be disposed on or cover at least a portion of the second semiconductor chip 210. In detail, the second molding layer 220 may extend along and cover the top and bottom surfaces and both side walls of the second semiconductor chip 210. At this time, the top surface of the second molding layer 220 may be at a higher vertical level than the top surface of the second semiconductor chip 210. However, embodiments are not limited thereto. Unlike what is illustrated in FIG. 5, the top surface of the second molding layer 220 may be coplanar with the top surface of the second semiconductor chip 210. In an embodiment, the second molding layer 220 may include an insulating polymer or epoxy resin. For example, the second molding layer 220 may include an EMC.

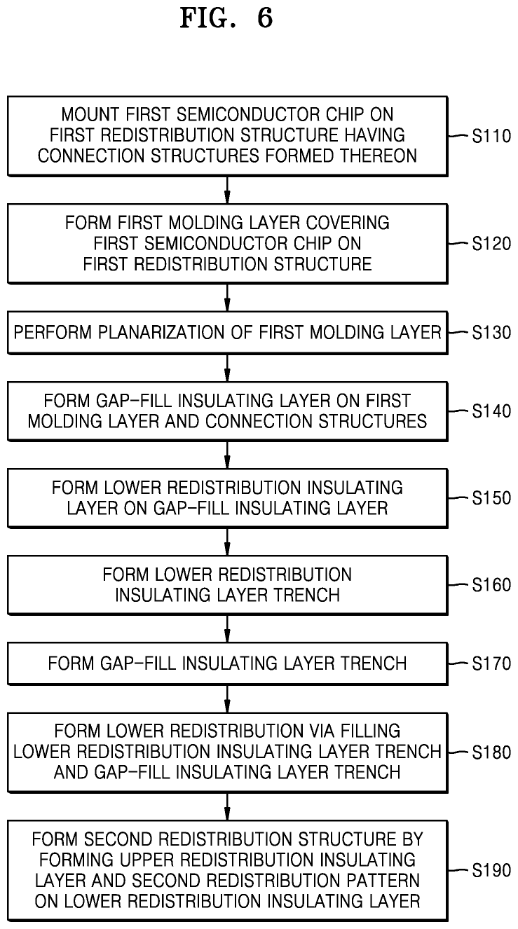

FIG. 6 is a flowchart of a method of manufacturing the semiconductor package 100, according to an embodiment. FIGS. 7A to 7I are cross-sectional views of stages in a method of manufacturing the semiconductor package 100, according to an embodiment.

Referring to FIGS. 6 and 7A, the first semiconductor chip 130 may be mounted on the first redistribution structure 110 in operation S110. A carrier substrate CS may be provided first. In an embodiment, the carrier substrate CS may include a semiconductor substrate, a glass substrate, a ceramic substrate, or a plastic substrate but is not limited thereto. Subsequently, the first redistribution structure 110 may be formed on the carrier substrate CS. At this time, the first redistribution insulating layer 111 may be formed by a lamination process, and the first redistribution pattern 113 may be formed by a plating process. In detail, the first redistribution structure 110 may be formed by repeating a process of forming the first redistribution lines 1131, a process of forming the first redistribution insulating layer 111 covering the first redistribution lines 1131, a process of forming a via hole (not shown) passing through the first redistribution insulating layer 111, and a process of forming a first redistribution via 1133 filling the via hole. Subsequently, a plurality of connection structures 120 may be formed on the first redistribution structure 110. For example, the connection structures 120 may be formed by forming a seed layer (not shown) and performing an electroplating process using the seed layer. Subsequently, the first semiconductor chip 130 may be mounted on the first redistribution structure 110. The first semiconductor chip 130 may be mounted on the first redistribution structure 110 via the first connection terminal BP1. When the first connection terminal BP1 is bonded to a first redistribution pad 115 and a first chip pad 133, the first semiconductor chip 130 may be fixed to the first redistribution structure 110.

Referring to FIGS. 6 and 7B, the first molding layer 140 may be formed to be disposed on or cover the connection structures 120 and the first semiconductor chip 130 in the resultant structure of FIG. 7A in operation S120. In this case, the first molding layer 140 may be formed to be disposed on or cover the top and bottom surfaces and both side walls of the first semiconductor chip 130 and the top surface and the side wall of each of the connection structures 120.

Referring to FIGS. 6 and 7C, planarization of the first molding layer 140 may be performed on the resultant structure of FIG. 7B in operation S130. For example, the planarization may include chemical mechanical planarization (CMP). According to the planarization, the top surface of the first molding layer 140 may be coplanar with the top surfaces of the connection structures 120. However, because of the planarization, a material, such as Cu, included in each of the connection structures 120 or a material, such as an EMC, included in the first molding layer 140 may be delaminated from the interface between the first molding layer 140 and each connection structure 120, and a material, such as a silica filler, included in the first molding layer 140 may come out of the top surface of the first molding layer 140. Accordingly, the first lower recess 140R1 may be formed at the interface between the first molding layer 140 and the connection structure 120, and the second lower recess 140R2 may be formed in the top surface of the first molding layer 140. The first lower recess 140R1 and the second lower recess 140R2 may degrade the structural reliability of the semiconductor package 100.

Referring to FIGS. 6 and 7D, the gap-fill insulating layer 150 may be formed on the first molding layer 140 and the connection structure 120 to fill or at least partially fill the first lower recess 140R1 and the second lower recess 140R2 in the resultant structure of FIG. 7C in operation S140. At this time, portions of the gap-fill insulating layer 150, which respectively overlap with the first lower recess 140R1 and the second lower recess 140R2 in the vertical direction, may respectively fill the first lower recess 140R1 and the second lower recess 140R2 and each thus be at a lower vertical level than the other portion of the gap-fill insulating layer 150, and accordingly, the gap-fill insulating layer 150 may have the first upper recess 150R1, which is at the lower vertical level and overlaps with the first lower recess 140R1 in the vertical direction, and the second upper recess 150R2, which is at the lower vertical level and overlaps with the second lower recess 140R2 in the vertical direction. In an embodiment, the gap-fill insulating layer 150 may include a non-PID.

Referring to FIGS. 6 and 7E, the lower redistribution insulating layer 161a may be formed on the gap-fill insulating layer 150 in the resultant structure of FIG. 7D in operation S150. At this time, the lower redistribution insulating layer 161a may fill the first upper recess 150R1 and the second upper recess 150R2. In an embodiment, the lower redistribution insulating layer 161a may include a PID. Subsequently, planarization of the lower redistribution insulating layer 161a may be performed such that the top surface of the lower redistribution insulating layer 161a may become flat.

Referring to FIGS. 6 and 7F, the lower redistribution insulating layer trench 161aT may be formed in the resultant structure of FIG. 7E in operation S160. At this time, because the lower redistribution insulating layer 161a includes a PID, the lower redistribution insulating layer trench 161aT may be formed by an exposure process and a development process.

Referring to FIGS. 6 and 7G, the gap-fill insulating layer trench 150T may be formed in the resultant structure of FIG. 7F in operation S170. At this time, because the gap-fill insulating layer 150 includes a non-PID, the gap-fill insulating layer trench 150T may be formed by an etching process using an etching gas. In an embodiment, the etching gas may include at least one of or one selected from the group consisting of O₂, N₂, CF₄, and Ar. In an embodiment, the etching process may include an etch back process. Although the gap-fill insulating layer trench 150T and the lower redistribution insulating layer trench 161aT have the same slope as each other in FIG. 7G, the gap-fill insulating layer trench 150T and the lower redistribution insulating layer trench 161aT may have different slopes from each other according to process conditions, as described with reference to FIGS. 4A and 4B above.

Referring to FIGS. 6 and 7H, a lower redistribution via 1633a may be formed to fill the gap-fill insulating layer trench 150T and the lower redistribution insulating layer trench 161aT in the resultant structure of FIG. 7G in operation S180.

Referring to FIGS. 6 and 7G, the second redistribution structure 160 may be completely formed in the resultant structure of FIG. 7H in operation S190. In detail, the second redistribution structure 160 may be completely formed by forming the upper redistribution insulating layer 161b, the upper redistribution vias 1633b, and the second redistribution lines 1631 on the lower redistribution insulating layer 161a and lower redistribution vias 1633a formed through the stages of FIGS. 7E to 7H. The upper redistribution insulating layer 161b, the upper redistribution vias 1633b, and the second redistribution lines 1631 may be formed by a method similar to the method of forming the first redistribution insulating layer 111 and the first redistribution pattern 113, which has been described with reference to FIGS. 6 and 7A. Subsequently, the carrier substrate CS may be removed from the bottom surface of the first redistribution structure 110.

Thereafter, the semiconductor package 100 of FIG. 1 may be completely formed by forming the external connection terminals 170 on the bottom surface of the first redistribution structure 110 in the resultant structure of FIG. 7I.

According to an embodiment, the semiconductor package 100 includes the gap-fill insulating layer 150 between the second redistribution structure 160 and the first molding layer 140, wherein the gap-fill insulating layer 150 is on the top surface of the first molding layer 140 and fills the first lower recess 140R1 and the second lower recess 140R2. Accordingly, the first lower recess 140R1 and the second lower recess 140R2, which are formed during the planarization of the first molding layer 140 because a filler comes out of the first molding layer 140 or the first molding layer 140 is delaminated from each of the connection structures 120, may be filled or at least partially filled with the gap-fill insulating layer 150. As a result, the structural reliability of the semiconductor package 100 may be increased.

While aspects of example embodiments have been particularly shown and described, it will be understood that various changes in form and details may be made therein without departing from the spirit and scope of the following claims.

1. A semiconductor package comprising:
a first redistribution structure;
a first semiconductor chip on the first redistribution structure;
a first molding layer on the first redistribution structure, the first molding layer comprising at least one lower recess at a top surface thereof and being disposed on the first semiconductor chip;
connection structures on the first redistribution structure, the connection structures extending in a vertical direction and passing through the first molding layer;
a first insulating layer on the first molding layer; and
a second redistribution structure comprising a lower redistribution insulating layer on the first insulating layer,
wherein the first insulating layer at least partially fills the at least one lower recess of the first molding layer.

2. The semiconductor package of claim 1, wherein a vertical thickness of the first insulating layer is smaller than a vertical thickness of the lower redistribution insulating layer.

3. The semiconductor package of claim 1, wherein the first insulating layer comprises a non-photo-imageable dielectric, and the lower redistribution insulating layer comprises a photo-imageable dielectric.

4. The semiconductor package of claim 1, wherein a viscosity of the first insulating layer is in a range from about 1000 cp to about 2000 cp.

5. The semiconductor package of claim 1, wherein a glass transition temperature of the first insulating layer is higher than a glass transition temperature of the lower redistribution insulating layer.

6. The semiconductor package of claim 1, wherein a 5% weight loss temperature of the first insulating layer is higher than a 5% weight loss temperature of the lower redistribution insulating layer.

7. The semiconductor package of claim 1, wherein the at least one lower recess comprises a first lower recess and a second lower recess, the first lower recess is at an interface between the first molding layer and each of the connection structures, and the second lower recess is at the top surface of the first molding layer.

8. The semiconductor package of claim 1, wherein the first insulating layer comprises at least one upper recess, and the lower redistribution insulating layer fills the at least one upper recess.

9. The semiconductor package of claim 8, wherein the at least one upper recess overlaps with the at least one lower recess in the vertical direction.

10. The semiconductor package of claim 9, wherein a length in a horizontal direction of the at least one upper recess is smaller than a length in the horizontal direction of the at least one lower recess that overlaps with the at least one upper recess in the vertical direction, and
wherein a length in the vertical direction of the at least one upper recess is smaller than a length in the vertical direction of the at least one lower recess that overlaps with the at least one upper recess in the vertical direction.

11. The semiconductor package of claim 1, wherein the second redistribution structure further comprises a lower redistribution via passing through the first insulating layer and the lower redistribution insulating layer.

12. The semiconductor package of claim 11, wherein a horizontal width of the lower redistribution via decreases toward the connection structures.

13. A semiconductor package comprising:
a lower semiconductor package;
an upper semiconductor chip mounted on the lower semiconductor package; and
an upper molding layer on the lower semiconductor package, the upper molding layer disposed on the upper semiconductor chip,
wherein the lower semiconductor package comprises:
a first redistribution structure;
a first semiconductor chip on the first redistribution structure;
a first molding layer on the first redistribution structure, the first molding layer comprising at least one lower recess in a top surface thereof, and being disposed on the first semiconductor chip;
connection structures on the first redistribution structure, the connection structures extending in a vertical direction and passing through the first molding layer;
a first insulating layer on the first molding layer; and
a second redistribution structure comprising a lower redistribution insulating layer on the first insulating layer,
wherein the first insulating layer at least partially fills the at least one lower recess of the first molding layer.

14. The semiconductor package of claim 13, wherein a vertical thickness of the first insulating layer is smaller than a vertical thickness of the lower redistribution insulating layer.

15. The semiconductor package of claim 13, wherein the first insulating layer comprises a non-photo-imageable dielectric, and the lower redistribution insulating layer comprises a photo-imageable dielectric.

16. The semiconductor package of claim 13, wherein a glass transition temperature and a 5% weight loss temperature of the first insulating layer are respectively higher than a glass transition temperature and a 5% weight loss temperature of the lower redistribution insulating layer.

17. The semiconductor package of claim 13, wherein the second redistribution structure further comprises a lower redistribution via passing through the first insulating layer and the lower redistribution insulating layer, and a horizontal width of the lower redistribution via decreases toward the connection structures.

18. A semiconductor package comprising:
a first redistribution structure;
a first semiconductor chip on the first redistribution structure;
a first molding layer on the first redistribution structure, the first molding layer disposed on the first semiconductor chip and comprising a first lower recess and a second lower recess in a top surface thereof,
connection structures on the first redistribution structure, the connection structures extending in a vertical direction and passing through the first molding layer;
a first insulating layer on the first molding layer; and
a second redistribution structure comprising a lower redistribution insulating layer and a lower redistribution via passing through the first insulating layer and the lower redistribution insulating layer,
wherein the first insulating layer comprises a non-photo-imageable dielectric, the lower redistribution insulating layer comprises a photo-imageable dielectric, and the first insulating layer at least partially fills the first lower recess and the second lower recess.

19. The semiconductor package of claim 18, wherein a vertical thickness of the first insulating layer is smaller than a vertical thickness of the lower redistribution insulating layer.

20. The semiconductor package of claim 18, wherein the connection structures comprise a conductive pillar comprising copper.

21-25. (canceled)
